(19) United States
(12) Patent Application Publication
(10) Pub. No.: US 2012/0240996 A1
(43) Pub. Date: Sep. 27, 2012

(54) MEMBRANE COMPRISING A SOLAR CELL

(75) Inventors: Stefan KEISER, Schwarzenberg (CH); Adrian MICHEL, Kerns (CH); Norman BLANK, Ruschlikon (CH); Josef LUSSI, Zermatt (CH); Heinz MEIER, Zurich (CH)

(73) Assignee: SIKA TECHNOLOGY AG, Baar (CH)

(21) Appl. No.: 13/437,751

(22) Filed: Apr. 2, 2012

Related U.S. Application Data
(63) Continuation of application No. PCT/EP2010/064528, filed on Sep. 30, 2010.

(30) Foreign Application Priority Data
Oct. 2, 2009 (EP) 09172034.2

(51) Int. Cl. H01L 31/0216

(52) U.S. Cl. 136/256

(57) ABSTRACT

In an exemplary embodiment, a membrane is disclosed having a barrier layer and a solar cell arranged on one side of the barrier layer. A compensation layer can be arranged between the solar cell and the barrier layer. This compensation layer can, for example, be a foamed composition composed of a thermoplastic that is solid at room temperature or a thermoplastic elastomer that is solid at room temperature.

### RELATED APPLICATION

This application claims priority as a continuation application under 35 U.S.C. §120 to PCT/EP2010/064528, which was filed as an International Application on Sep. 30, 2010 designating the U.S., and which claims priority to European Application 09172034.2 filed in Europe on Oct. 2, 2009. The entire contents of these applications are hereby incorporated by reference in their entireties.

### FIELD

The present disclosure is directed to the field of photovoltaic cells, such as for placement on roofs.

### BACKGROUND INFORMATION

The placement of solar cells on roofing by adhesives is known. With this type of fastening, however, the solar cells can become loosened from the roofing due, for example, to mechanical stresses, and hollows can form in between. The subsequent penetration of moisture into these hollows can have a detrimental effect on the connection due, for example, to damaging of the adhesive, the solar cell and the roofing, and this can promote further loosening.

The mentioned stresses are occasioned for example, by horizontal and vertical shifting of solar cell and roofing relative to each other, such as on account of different thermal coefficients of elongation of the two layers. Such stresses can occur upon heating by intense solar radiation or during low outdoor temperatures.

### SUMMARY

A membrane is disclosed, comprising: a barrier layer; a solar cell arranged on one side of the barrier layer; and a compensation layer arranged between solar cell and barrier layer, wherein the compensation layer is a foamed composition composed of a thermoplastic that is solid at room temperature or a thermoplastic elastomer that is solid at room temperature.

### BRIEF DESCRIPTION OF THE DRAWINGS

In the following discussion, exemplary embodiments will be explained more fully by reference to the drawings. The same elements are provided with the same reference numbers in the different figures, wherein:

FIG. 1 shows a cross section through an exemplary membrane as disclosed herein;

FIG. 2 shows a further cross section through an exemplary membrane as disclosed herein;

FIG. 3 shows a further cross section through an exemplary membrane as disclosed herein; and

FIG. 4 shows exemplary side seals by way of cross sections through an exemplary membrane as disclosed herein.

Elements are provided in the drawings sufficient for those skilled in the art to gain immediate understanding of the exemplary embodiments.

### DETAILED DESCRIPTION

Exemplary embodiments are directed to a membrane which can address the loosening of solar cells placed on roofing so that subsequent formation of hollows and the consequent penetration of moisture can be minimized.

In an exemplary embodiment, a membrane is disclosed having a barrier layer and a solar cell arranged on one side of the barrier layer. A compensation layer can be arranged between the solar cell and the barrier layer. This compensation layer can, for example, be a foamed composition composed of a thermoplastic that is solid at room temperature or a thermoplastic elastomer that is solid at room temperature.

The foamed composition can be a closed-pore composition, so that no moisture can penetrate through the compensation layer between barrier layer and solar cell.

Exemplary embodiments can use materials for the compensation layer that can equalize mechanical stresses due to horizontal and vertical shifting of a solar cell and a barrier layer relative to each other, such as those caused by different thermal coefficients of elongation of the two layers.

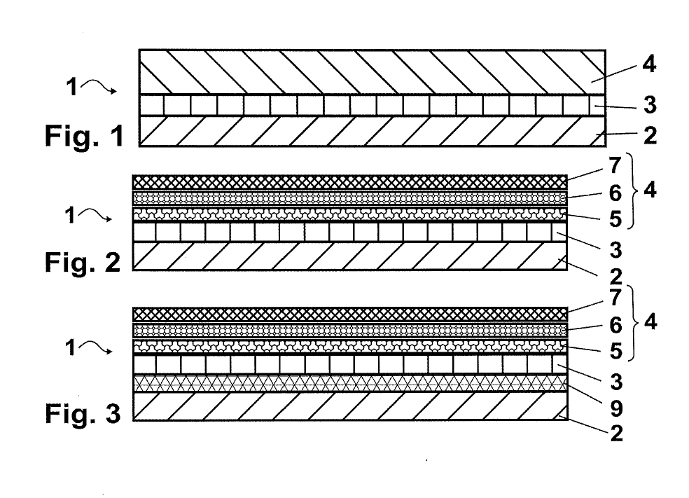

In FIG. 1 there is depicted an exemplary membrane 1, comprising a barrier layer 2, a solar cell 4 arranged on one side of the barrier layer, as well as a compensation layer 3 arranged between solar cell and barrier layer, wherein the compensation layer is a foamed composition composed of a thermoplastic that is solid at room temperature or a thermoplastic elastomer that is solid at room temperature.

As referenced herein, the term “membrane” refers to a sheet-like body, such as is known for the sealing of subfloors against water penetration in the construction industry, for example, as a structure seal, such as a roof membrane.

As referenced herein, the term “foamed composition” refers to a structure of spherical or polyhedral pores that are bounded by webs and form a cohesive system.

As referenced herein, “pores” refers to fabrication-related cavities in and/or on the surface of a composition that are filled with air or other substances foreign to the composition. The pores can be recognizable to the naked eye or not. They can be open pores, in communication with the surrounding medium, or closed pores, enclosed in themselves and not letting through any medium. Furthermore, a mixed form of open and closed pores can also be included.

An exemplary closed-pore compensation layer can be advantageous in that no moisture can penetrate through the compensation layer 3 between barrier layer 2 and solar cell 4.

It can also be advantageous for an exemplary foamed composition to have a pore size of 0.1-3 mm, especially for example 0.2-1 mm and/or a pore volume of 5-99%, especially for example 30-98%. As referenced herein, a pore volume refers to a percentage of a totality of cavities filled with air or other substances foreign to the composition in the volume of the foamed composition.

Closed-pore foamed compositions, such as those with a pore size smaller than 1 mm, can be preferable in certain exemplary embodiments because of their higher mechanical stability.

Moreover, exemplary advantageous materials for the compensation layer 3 are those which can equalize stresses from horizontal and vertical shifting of a solar cell and a barrier layer relative to each other, such as due to different thermal coefficients of elongation of the two layers.

Such mechanical stresses can occur for example by heating of the membrane, such as a solar cell, under intense solar radiation or during low outdoor temperatures. A decoupling of such stresses can be of advantage in that it can prevent a detachment of solar cell 4 from the barrier layer 2 and a penetration of moisture into the space in between. The penetration of moisture can, for example, have a detrimental effect on the bond of a solar cell and barrier layer and can encourage further loosening. Moreover, corrosion of the conductor tracks can occur.

As compared to the direct bonding of solar cell 4 to the barrier layer 2 by means of traditional adhesives, foamed compositions can achieve a greater layer thickness of the bond between solar cell and barrier layer, which can have positive impact on the decoupling of stresses; moreover, foamed compositions can have only very limited tendency to creep under elevated temperature. The low creep tendency is due, for example, to the adjustable degree of cross-linking and the different molecular weight, and foamed compositions retain their geometry for a longer time. Moreover, some foamed compositions can be easily bonded to the barrier layer or the solar cell by heating, such as welding or calendaring. Moreover, foamed compositions can better withstand tensile and shear forces due to their porous structure.

In exemplary embodiments, the compensation layer 3 can have a density of 0.02-1.2 g/cm³, preferably for example 0.03-0.8 g/cm³, especially preferably for example 0.05-0.5 g/cm³.

A lower density of the foamed composition can be of advantage in that less thermal energy can be involved for the welding of the foamed composition.

Exemplary embodiments can provide an advantage of a compensation layer 3 having a high electrical insulation resistance. Furthermore, good thermal insulating properties can be of advantage.

The compensation layer 3 can be a foamed composition composed of a thermoplastic that is solid at room temperature or a thermoplastic elastomer that is solid at room temperature.

As referenced for exemplary embodiments described herein, the term “room temperature” refers to an exemplary temperature of 23° C. Thermoplastic elastomers have the advantage that the compensation layer in this way has a good elasticity to horizontal and vertical displacements, such as displacements of the solar cell relative to the barrier layer. A good elasticity of the barrier layer can prevent a tearing or detachment and thus a failure of the compensation layer. In exemplary embodiments, the compensation layer has a tearing resistance σ_{B} of 0.1-10 MPa at room temperature and/or an elongation at break ε_{R} of 5-1000%, both measured according to DIN ISO 527.

As referenced herein, thermoplastic elastomers refers to plastics which combine the mechanical properties of vulcanized elastomers with the processing ease of thermoplastics. For example, such thermoplastic elastomers can be block copolymers with hard and soft segments or so-called polymer alloys with corresponding thermoplastic and elastomeric components.

Exemplary preferred thermoplastics and thermoplastic elastomers are chosen from the group consisting of polyethylene (PE), low-density polyethylene (LDPE), ethylene/vinyl acetate copolymer (EVA), polybutene (PB); thermoplastic elastomers on an olefin basis (TPE-O, TPO) such as ethylene-propylene-diene/polypropylene copolymers; cross-linked thermoplastic elastomers on an olefin basis (TPE-V, TPV); thermoplastic polyurethanes (TPE-U, TPU), such as TPU with aromatic hard segments and polyester soft segments (TPU-ARES), polyether soft segments (TPU-ARET), polyester and polyether soft segments (TPU-AREE) or polycarbonate soft segments (TPU-ARCE); thermoplastic copolyesters (TPU-E, TPC) such as TPC with polyester soft segments (TPC-ES), polyether soft segments (TPC-ET) or with polyester and polyether soft segments (TPC-EE); styrene block copolymers (TPE-S, TPS) such as styrene/butadiene block copolymers (TPS-SBS), styrene/isoprene block copolymers (TPS-SIS), styrene/ethylene/butylene/styrene block copolymers (TPS-SEBSS), styrene/ethylene-propylene/styrene block copolymers (TPS-SEPS); and thermoplastic copolyamides (TPE-A, TPA).

Preferably for example, the compensation layer 3 is a foamed composition made from a material that is chosen from the group consisting of acrylate compounds, acrylate copolymers, polyurethane polymers, silane-terminated polymers and polyolefins, especially for example one made of polyolefins.

Polyethylene (PE) can, for example, be especially preferred as the polyolefin.

Preferably, the compensation layer 3 can be, for example, a foamed composition with low moisture uptake, which in addition can be easily joined to the barrier layer.

The compensation layer 3 can be directly joined to the barrier layer 2. As referenced herein, the term “directly joined” means that no other layer or substance is present between the two materials and that the two materials are directly joined to each other, or adhere to each other. This is shown, for example, in FIG. 1 and FIG. 2. The two materials can be mixed together at the transition between the two materials.

The compensation layer 3 can essentially be arranged firmly against the barrier layer 2. This can be accomplished, for example, in that the compensation layer and the barrier layer are directly joined together during the manufacture of the membrane by the action of heat, by pressure, by physical absorption or by any other application of suitable physical force. This can have an exemplary advantage in particular that no chemical combination of barrier layer and compensation layer by means of adhesives is needed, which can have a favorable impact on the manufacturing costs of the membrane 1. For example, the barrier layer and compensation layer can be joined together by lamination. By lamination, a strong bond can be achieved between a compensation layer and barrier layer, especially when the two of them include (i.e., consist of) PE or materials that are compatible with each other. In addition, the bonding quality can be more dependable when lamination is used to manufacture the membranes and they are subject to less fluctuation in the production parameters than when adhesives are used for the bonding.

However, the possibility also exists of joining together the compensation layer and barrier layer by a glue coat 9, as is shown for example in FIG. 3. This can be especially advantageous when a lamination of the compensation layer to the barrier layer is not advisable due to the materials.

An adhesive used in such a glue coat 9 can be, e.g., a pressure-sensitive mass and/or a hot-melt adhesive. This can assure a good bond and a good adhesion of the compensation layer 3 to the barrier layer 2 and thus can reduce the loosening of the compensation layer and thus a failure of the compensation layer. The adhesive can also provide a barrier action against diffusion and migration of contents of the membranes.

Pressure-sensitive masses and hot-melt adhesive are generally known to the skilled person in the art and are described, for example, in C D Römpp Chemie-Lexikon, Version 1.0, Georg Thieme Verlag, Stuttgart.

An exemplary preferable adhesive is one chosen from the group consisting of ethylene/vinyl acetate copolymer (EVA), cross-linked thermoplastic elastomers on an olefin basis, acrylate compounds, polyurethane polymers and silane-terminated polymers.

Exemplary preferred acrylate compounds are in particular acrylate compounds on the basis of acrylic monomers, especially acrylic and methacrylic acid esters.

The term “polyurethane polymer” subsumes all polymers that are produced by the so-called diisocyanate polyaddition process. This also includes polymers that are almost or entirely free of urethane groups. Examples of polyurethane polymers are polyether-polyurethanes, polyester-polyurethanes, polyether-polyresins, polyresins, polyester-polyresins, polyisocyanurates and polycarbodiimides.

Exemplary preferred adhesives are commercially available under the brand SikaLastomer®-68 from Sika Corporation, USA.

By surface treatments such as corona treatment, fluorination, plasma treatment and flame treatment of the compensation layer 3 and/or the barrier layer 2, the adhesion of the compensation layer or a possible adhesive to the compensation layer and/or the barrier layer can be improved.

A flexible membrane 1 makes possible a roll-up, which facilitates its storage, transport and placement on a subflooring.

The barrier layer 2 can, for example, include any materials that assure a sufficient tightness, even under high fluid pressure.

It can thus be advantageous for the barrier layer 2 to have a good resistance to water pressure and the elements, as well as good values in crack propagation tests and perforation tests, which can be of special advantage for mechanical loads at construction sites. Furthermore, a resistance to ongoing mechanical loads, especially wind, can be of advantage.

The barrier layer can include (e.g., consist of) a rigid material such as aluminum, steel, plastic-coated sheet, plastic slabs, or be otherwise flexible. Preferably, it is for example a flexible material.

It can be especially advantageous when the barrier layer 2 has a thermoplastic layer, preferably for example a layer of thermoplastic polyolefins or polyvinyl chloride (PVC), especially for example a layer of polypropylene (PP) or polyethylene (PE), especially preferably for example one of polypropylene. This can result in good resistance to environmental influences.

The barrier layer 2 can be selected from materials from the group consisting of high-density polyethylene (HDPE), medium-density polyethylene (MDPE), low-density polyethylene (LDPE), polyethylene (PE), polyvinyl chloride (PVC), ethylene/vinyl acetate copolymer (EVA), chlorosulfonated polyethylene, thermoplastic elastomers on an olefin basis (TPE-O, TPO), ethylene-propylene-diene rubber (EPDM) and polyisobutylene (PIB), as well as mixtures of these.

The barrier layer 2 can have an exemplary density of 0.05-3 mm, preferably for example 0.08-2.5 mm, or more preferably for example 1-2 mm.

The solar cell 4 can include (e.g., consist of) a substrate layer 5, a photovoltaic layer 6 and possibly a cover layer 7, as is shown for example in FIGS. 2 and 3.

The cover layer 7 is for example plastic having a low UV absorption. Suitable materials for the cover layer are fluoropolymers, such as copolymers of ethylene and tetrafluorethylene, such as are marketed by the DuPont Corporation under the brand name Tefzel®, or a polyvinylidene fluoride, marketed by the DuPont Corporation under the brand name Tedlar®, or other suitable materials.

The substrate layer 5 can be, for example, a steel sheet, a PET film, or a polyimide film.

It can be advantageous for the membrane to have a lateral closure 8. The lateral closure should protect the contact sites of the solar cell 4 with the compensation layer 3 that are situated on the outer lateral side of the membrane 1 from moisture and, consequently, from delamination and failure. This can be especially advantageous when cavities have formed at the contact surfaces of compensation layer 3 and barrier layer 2, or solar cell 4, on account of stresses.

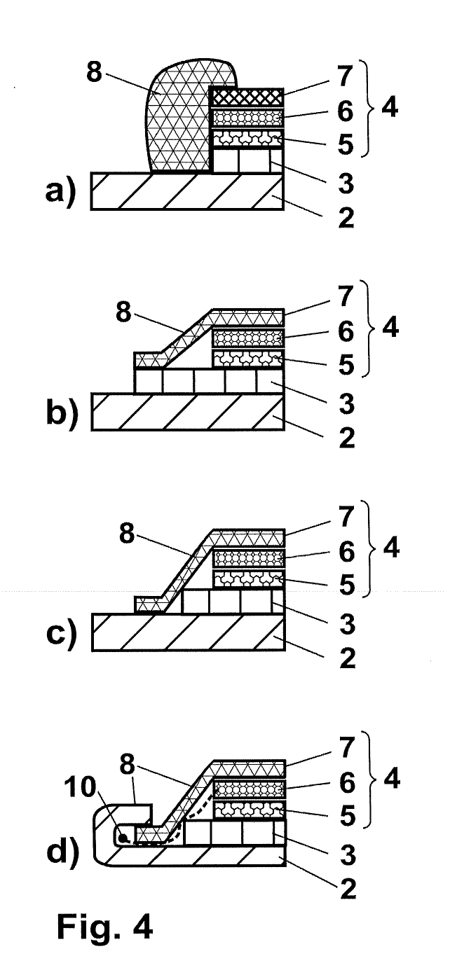

The lateral closure can be a plastic, which is in contact with the solar cell, the compensation layer and the barrier layer, as shown in FIG. 4a. For example, the barrier layer 2 projects beyond the solar cell 4 and the compensation layer 3 at the side, for example by up to 10 mm (or greater), which can achieve a better sealing performance of the lateral closure.

The lateral closure can also involve the cover layer 7, which projects laterally beyond the photovoltaic layer 6, or the substrate layer 5, and is joined to the compensation layer 3, as is shown for example in FIG. 4b. If the entire compensation layer is protected laterally against moisture by the substrate layer, this can be additionally beneficial to the bonding of the compensation layer with the barrier layer. This is shown in FIG. 4c.

In such a lateral closure, the cover layer 7 can also project laterally beyond the photovoltaic layer 6, or the substrate layer 5, and beyond the compensation layer 3 and be joined to the barrier layer 2. The bonding can, for example, occur by gluing or welding, especially welding. FIG. 4d shows such an exemplary embodiment.

The sealing effect of the latter mentioned option for a lateral closure can be further improved if the barrier layer encloses the cover layer laterally and forms a flanged fold. An exemplary advantage of such a solution is that any existing means for electrical connection 10 of the photovoltaic layer in the flanged fold can be protected against moisture. This can be especially advantageous for means of electrical connection 10.

The membrane 1 can be manufactured in any given way. For example, the membranes can be produced on known machines. The membranes can be made in a single process step as endless products, for example, by extrusion and/or calendering and/or lamination, and be rolled up into rolls, for example. The temperature of the mass in the extruder or calendering roller can lie in an exemplary range of 100° C.-210° C., preferably for example 130° C.-200° C., or more especially for example 170° C.-200° C. during, for example, the extrusion and/or the calendering and/or the lamination.

The compensation layer 3 can be applied during exemplary manufacturing by broad-slot nozzle extrusion, by melt calendering, by band pressing with IR irradiation, by flame lamination or spray lamination or other suitable technique. It can be advantageous for the compensation layer to have a composition and a stability that is consistent with the temperatures of manufacture of the membrane 1.

For example, the compensation layer 3 can be joined to the barrier layer 2 by lamination. For example, the lamination can be by band pressing with IR irradiation. The bonding to the barrier layer, however, can also occur by adhesives, as mentioned herein. Furthermore, a pretreatment of the barrier layer, as mentioned herein, can also be of advantage, for example, by flame treatment and corona treatment.

The bonding of the compensation layer 3 to the solar cell 4, or to the substrate layer 5 of the solar cell, can occur for example by lamination, such as flame lamination; but the bonding can also occur through adhesives, as mentioned herein or by other suitable processes.

In an exemplary production of the membrane 1, the solar cell 4, or the substrate layer 5 of the solar cell, and the barrier layer 2 are joined to the compensation layer 3 by lamination. Moreover, the cover layer 7 is joined by welding to the barrier layer projecting laterally. For example, the barrier layer is additionally flanged about the outer end of the cover layer and welded, as described herein.

Of course, the invention is not limited to the exemplary embodiments depicted and described herein.

Rather, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE NUMBERS

1 membrane
2 barrier layer
3 compensation layer
4 solar cell
5 substrate layer
6 photovoltaic layer
7 cover layer
8 lateral closure
9 glue coat
10 means of electrical connection

What is clamed is:

1. A membrane, comprising
a barrier layer;
a solar cell arranged on one side of the barrier layer; and
a compensation layer arranged between solar cell and barrier layer, wherein the compensation layer is a foamed composition composed of a thermoplastic that is solid at room temperature or a thermoplastic elastomer that is solid at room temperature.

2. A membrane according to claim 1, wherein the compensation layer is a closed-pore foamed composition.

3. A membrane according to claim 1, wherein the compensation layer is a foamed composition with a pore size of 0.1-3 mm and/or a pore volume of 5-99%.

4. A membrane according to claim 1, wherein the compensation layer has a density of 0.02-1.2 g/cm.

5. A membrane according to claim 1, wherein the compensation layer is a foamed composition made from a material that is chosen from the group consisting of: acrylate compounds, acrylate copolymers, polyurethane polymers, silane-terminated polymers and polyolefins.

6. A membrane according to claim 1, wherein the compensation layer is directly joined to the barrier layer.

7. A membrane according to claim 1, wherein the compensation layer and barrier layer are joined together by a glue coat.

8. A membrane according to claim 7, wherein the glue coat comprises:
a pressure-sensitive mass and/or a hot-melt adhesive.

9. A membrane according to claim 8, wherein the glue coat comprises:
an adhesive chosen from the group consisting of: ethylene/vinyl acetate copolymer (EVA), cross-linked thermoplastic elastomers on an olefin basis, acrylate compounds, polyurethane polymers and silane-terminated polymers.

10. A membrane according to claim 1, wherein the barrier layer has a thermoplastic layer.

11. A membrane according to claim 1, wherein the barrier layer has a density of 0.05-3 mm.

12. A membrane according to claim 1, wherein the membrane has a lateral closure.

13. A membrane according to claim 1, wherein the compensation layer is a foamed composition with a pore size of 0.2-1 mm and/or a pore volume of 30-98%.

14. A membrane according to claim 1, wherein the compensation layer has a density of 0.03-0.8 g/cm³.

15. A membrane according to claim 1, wherein the compensation layer has a density of 0.05-0.5 g/cm³.

16. A membrane according to claim 1, wherein the barrier layer has a layer of thermoplastic polyolefins or polyvinyl chloride (PVC).

17. A membrane according to claim 1, wherein the barrier layer has a density of 0.08-2.5 mm.

18. A membrane according to claim 1, wherein the barrier layer has a layer of polypropylene (PP) or polyethylene (PE).

19. A membrane according to claim 1, wherein the barrier layer has a density of 1-2 mm.

20. A membrane according to claim 1, wherein the compensation layer is a foamed composition made of polyolefins.
